(19) United States
(12) Patent Application Publication
(10) Pub. No.: US 2002/0162571 A1
(43) Pub. Date: Nov. 7, 2002

(54) Planar clean method applicable to shallow trench isolation

(76) Inventors: Chun Lien Su, Shanhua (TW); Chun Chi Wang, Nantou (TW); Gen Da You, I-Lan (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 09/846,184

(22) Filed: May 2, 2001

(51) Int. Cl. B08B 3/00; C23G 1/00; C03C 23/00; B08B 7/00; B44C 1/22; C03C 25/68; H01L 21/461; H01L 21/302; C03C 15/00; C23F 1/00; B08B 3/14; B08B 9/00

(52) U.S. Cl. 134/2; 134/22.1; 134/22.19; 134/26; 134/36; 134/42; 134/902; 438/748; 438/756; 216/92

(57) ABSTRACT

The present invention provides a planar clean method applicable to shallow trench isolation (STI) for cleaning a substrate having a STI region formed thereon and a high density plasma (HDP) oxide on the surface of the STI region. A buffer oxide etch cleaning solution is exploited and matched by a planar clean way to let the oxide losses of the surface of the silicon substrate and the STI corners match the height and shape of the HDP oxide in the STI region. Thereby, the phenomenon of wrap rounding at the STI corners, which influences growth of the next thermal oxide, can be avoided. The present invention can prevent the STI corners from generating parasitic device characteristics and enhance electric characteristics of the device.

### FIELD OF THE INVENTION

The present invention relates to a clean method of a shallow trench isolation region and, more particularly, to a clean method of a shallow trench isolation region capable of effectively restraining the problem of oxide loss and enhancing device characteristics.

### BACKGROUND OF THE INVENTION

In the semiconductor fabrication process, before wafers enter a high-temperature oven to perform diffusion or oxidation, or before or after chemical vapor deposition (CVD) and thin film deposition, the wafers must undergo a clean procedure to achieve very high cleanliness on the surfaces thereof so that fabricated semiconductor devices can conform to designed electrical characteristics.

In a clean method shown in FIG. 1, a single wafer 10 to be cleaned is placed on a rotation disk 14 in a clean tank, and a chemical clean solution 12 is sprayed vertically and uniformly through a spray post 26 on the rotating wafer 10. In a conventional clean method, several tens of wafers along with a boat are immersed in a chemical bath to be cleaned by the flow of the chemical clean solution.

Parasitic device characteristics such as the problems of double hump, high electric field, and leakage current easily arise in the structure of shallow trench isolation used in the present industry so that electric characteristics of semiconductor cannot be effectively exploited. Reasons of these phenomena probably come from damage of device resulted from inappropriate clean way of wafer. As shown in FIG. 2, a shallow trench isolation region 18 is formed on a silicon substrate 16. Cleaning action is then performed using one of the above clean methods of wafer after a CVD high density plasma (HDP) oxide 20 is deposited thereon. However, this kind of clean method easily results in loss of the oxide 20 of STI corners 22 so as to generate wrap roundings 24, hence being not able to cover the STI corners 22. Therefore, when performing the next thermal oxidation, the wrap roundings 24 will bring forth nonuniform growth of thermal oxide, hence generating the above parasitic device characteristics at the STI corners. The present invention aims to propose a clean method for preventing the STI corners from generating wrap roundings so as to resolve the above problems.

### SUMMARY OF THE INVENTION

The primary object of the present invention is to provide a wafer clean method to effectively restrain oxide loss at STI corners for preventing the STI corners from generating parasitic device characteristics due to generated wrap roundings, and to enhance semiconductor device characteristics.

Another object of the present invention is to utilize existent chemical solutions to effectively restrain oxide loss so that manpower and cost need not be wasted on the control of uniformity of oxide growth.

According to the present invention, a planar clean method of a buffer oxide etch (BOE) is exploited to perform planar cleaning to a silicon substrate having an STI region formed on the surface thereof and a CVD HDP oxide deposited on the surface of the STI region. Thereby, the phenomenon of wrap rounding generated at the STI corners can be avoided.

The various objects and advantages of the present invention will be more readily understood from the following detailed description when read in conjunction with the appended drawings, in which:

### BRIEF DESCRIPTION OF THE DRAWINGS

FIG. 1 is a diagram showing a prior art wafer clean method;

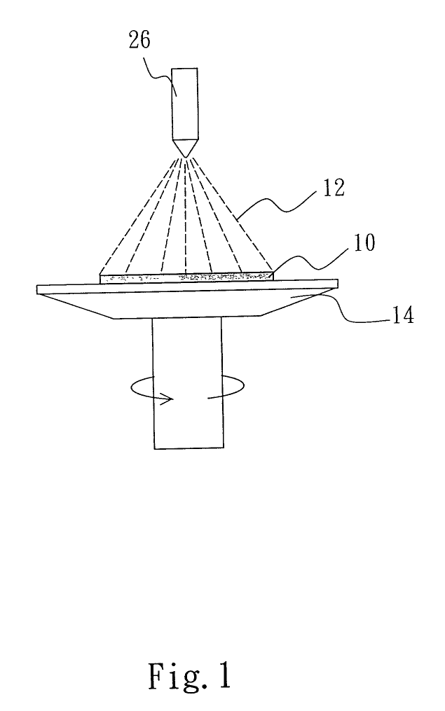

FIG. 2 is a diagram showing the phenomenon of wrap rounding at STI corners in the prior art; and

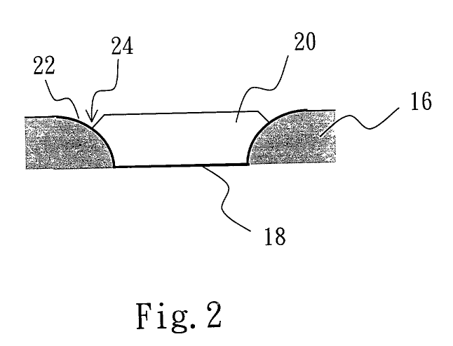

FIGS. 3a to 3c are diagrams showing cleaning procedures of the present invention.

### Detailed description of the preferred embodiments

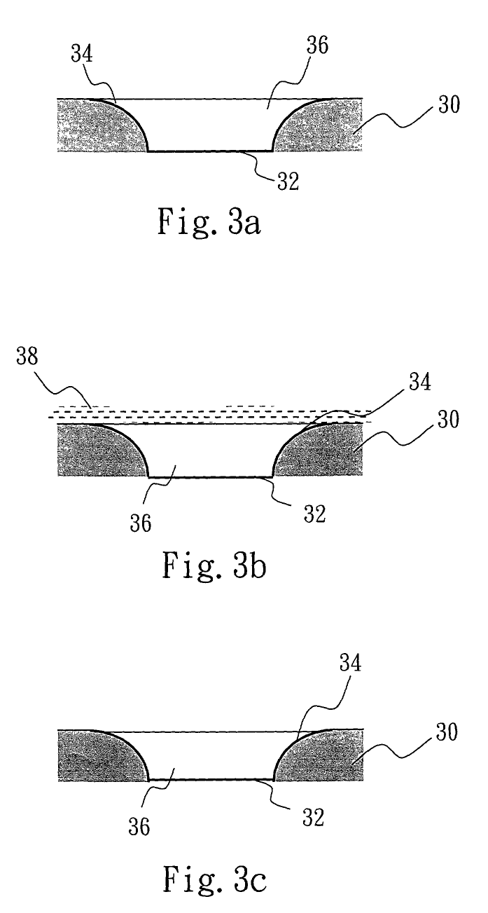

As shown in FIG. 3a, an STI region 32 with STI corners 34 of rounding shape at two edges thereof is formed on a silicon substrate 30. An HDP oxide 36 is deposited on the surface of the STI region 32. In addition to filling the whole STI region 32, the HDP oxide 36 also covers the STI corners 34. The cleaning action is performed by letting a BOE cleaning solution 38 uniformly flow over the surfaces of the silicon substrate 30 and the HDP oxide 36, as shown in FIG. 3b. Surfactant of the BOE cleaning solution 38 has a lower selectivity so that cleaning losses of the surface of the silicon substrate 30 and the STI corners 34 are compatible and uniform. A planar clean way is also exploited to effectively restrain loss of oxide to match the height and shape of the HDP oxide 36 in the STI region 32 when the surface of the silicon substrate 30 and the HDP oxide 36 of the STI corners 34 are cleaned. As shown in FIG. 3c, the HDP oxide 36 of the cleaned silicon substrate 30 will still uniformly cover the STI region 32 and the STI corners 34 so that the phenomenon of wrap will not occur. Therefore, nonuniform growth of oxide, which results in the problems of high electric field and leakage current, will not arise from wrap rounding at the STI corners 34 when performing the next thermal oxidation. Moreover, double hump will not occur because the surfaces of the STI corners 34 are covered by the HDP oxide 36.

In the present invention, the BOE cleaning solution 38 is exploited and matched by a planar clean way to not only effectively restrain loss of the HDP oxide but also let the STI region and the HDP oxide not generate defects due to the cleaning action so that parasitic device characteristics will not be generated at deposited edges of the next thermal oxidation. Thereby, device characteristics can be effectively enhanced, and the growth of thermal oxide will be uniform. Therefore, it is not necessary to waste time and manpower to improve the nonuniform growth of oxide due to wrap of the STI corners. The present invention thus has the advantage of saving the cost.

Although the present invention has been described with reference to the preferred embodiment thereof, it will be understood that the invention is not limited to the details thereof. Various substitutions and modifications have been suggested in the foregoing description, and other will occur to those of ordinary skill in the art. Therefore, all such substitutions and modifications are intended to be embraced within the scope of the invention as defined in the appended claims.

I claim:

1. A planar clean method applicable to shallow trench isolation, a shallow trench isolation region being formed on a substrate, a high density plasma oxide being deposited on a surface of said shallow trench isolation region, said high density plasma oxide covering corners of said shallow trench isolation region, said clean method comprising the steps of:
providing a buffer oxide etch cleaning solution; and
letting said buffer oxide etch cleaning solution levelly and uniformly flow over surfaces of said substrate and said high density plasma oxide to perform the cleaning action.

2. The planar clean method applicable to shallow trench isolation as claimed in claim 1, wherein said cleaned high density plasma oxide still covers said shallow trench isolation corners.

3. The planar clean method applicable to shallow trench isolation as claimed in claim 1, wherein surfactant of said buffer oxide etch cleaning solution has a lower selectivity.

4. The planar clean method applicable to shallow trench isolation as claimed in claim 1, wherein said substrate is a silicon substrate.
